(19) United States
(12) Patent Application Publication
(10) Pub. No.: US 2006/0042682 A1
(43) Pub. Date: Mar. 2, 2006

(54) Photovoltaic building elements

(75) Inventors: Philip Rowland Wolfe, North Moreton (GB); Spencer William Jansen, South Brent (GB)

Correspondence Address: LACASSE & ASSOCIATES, LLC, 1725 DUKE STREET, SUITE 650, ALEXANDRIA, VA, 22314, US

(73) Assignee: ICP Solar Technologies Inc., Montreal (CA)

(21) Appl. No.: 10/932,196

(22) Filed: Sep. 2, 2004

(51) Int. Cl. H01L 25/00

(52) U.S. Cl. 136/251; 136/244

(57) ABSTRACT

An external building element has the size and shape of a standard roofing or building product but incorporates a monolithically interconnected solar cell array within which a plurality of interconnected thin film solar cells are integrated on an electrically insulating substrate. The cells are positioned in one or more rows with the cells being electrically connected together in series and being connected by electrically conducting tracks to two output tracks. The output tracks of each element may be automatically interconnected to the output tracks of the adjacent elements when the elements are placed adjacent one another along a horizontal support rail so as to electrically connect the solar cell assemblies of the elements in parallel. Further similar elements may be positioned in overlapping rows. Such an element incorporating a solar cell array is substantially uniform in colour and may be designed to provide a very close visual match to standard building products, such as natural and synthetic slates. The array is configured to provide a peak power voltage in excess of 20V and an open circuit voltage below 75V. The peak power voltage exceeds 150V per m² of active solar cell area.

This invention relates to elements for forming parts of the external envelope of a building, and is concerned, more particularly, with such elements, for use as roofing slates, tiles or panels or building cladding or façade panels for example, incorporating photovoltaic solar cells for generating electrical power from received light energy.

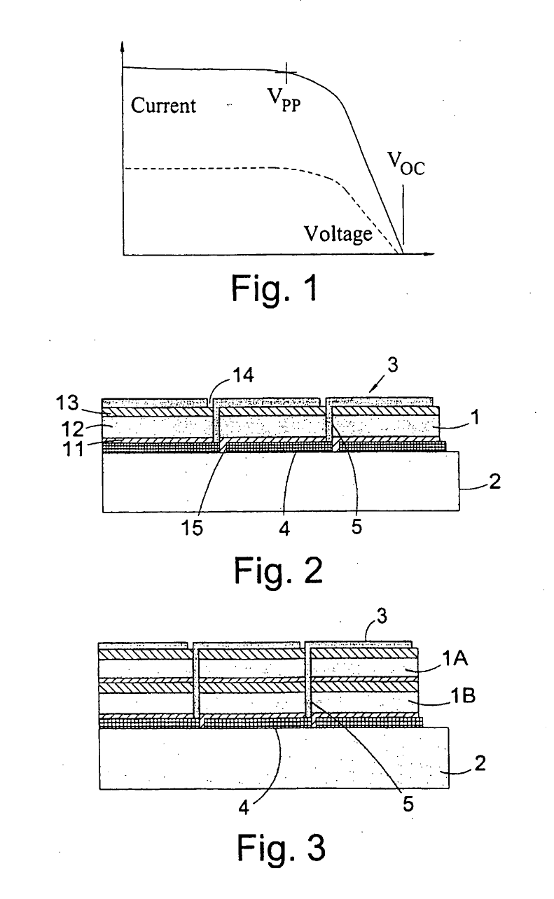

As is well-known in the field of photovoltaics (PV) light energy may be converted to DC electricity by photovoltaic conversion devices typically known as “solar cells”. Such solar cells are typically crystalline cells made predominantly of silicon in mono-crystalline or poly-crystalline form and having a typical thickness in excess of 100 microns. However it has now become possible to produce solar cells in the form of thin film devices formed on a support substrate and typically having a thickness of less than 5 microns. The voltage produced by a solar cell under daylight conditions is a function primarily of the materials used, whereas the current produced is a function primarily of the area of the cell and the level of instant light radiation. The level of radiation at which solar cell performances are normally rated is 1 kWm⁻² at a light spectrum AM1.5 defined by international standards. Typical solar cells have electrical characteristics under standard conditions as shown in FIG. 1 where the open circuit voltage V_{OC} is in the range 0.5 to 0.8V and the peak power voltage V_{PP} is in the range of 0.3 to 0.6 volts. At different illumination levels (typically 5% to 10% standard) the voltage remains substantially the same whereas the current varies broadly proportionally with illumination. To optimise performance systems are normally designed such that each cell operates close to the peak power point.

Furthermore solar cells arc commonly connected together in series and/or in parallel to produce a solar cell array. Series connection increases the voltage and parallel connection increases the current. For most applications, voltages in excess of 1V are required, so that a multiplicity of series-connected cells are used. For most types of solar cell array, each cell is a discrete mechanically independent unit, and series connection is therefore achieved by contacting each cell with its neighbour, typically by soldering, welding or bonding, either directly or through an interconnect tab. For thin film solar cell arrays produced on an insulating substrate, however, such interconnection may be made within the thin film structure as part of the production process, without the individual cells ever being handled as separate entities.

Such monolithic interconnection is achieved by a series of sequential isolation and deposition steps producing a structure as shown in FIG. 2 in which a series of solar cells 1 is supported on top of contact regions 4 on a non-conductive (e.g. glass) substrate 2, with the contact regions 4 being separated from one another by isolation areas 15. Each solar cell 1 comprises p-type, intrinsic and n-type layers 11, 12 and 13 producing a p-i-n junction between a respective one of the contact regions 4 and a second contact region 3 on the opposite surface of each cell, adjacent contact regions 3 being separated by isolation areas 14 slightly offset from the isolation areas 15. Adjacent solar cells 1 are interconnected by way of a connection part 5 passing through an inter-cell isolation region. Such monolithic interconnection facilitates a relatively large number of series interconnections between cells within a defined area with relatively low associated cost. The division of each layer into regions may be effected either as a part of each fabrication step (for example by masking) or during a subsequent etching, laser oblation or mechanical scribing step, for example.

Thin film cells may be designed to trap and convert certain frequencies of light allowing others to penetrate through the cell. This permits the production of cell stacks, known as multijunction or tandem cells, incorporating a multiplicity of superimposed solar cells, each cell being designed to convert a different part of the visible light spectrum. FIG. 3 shows such a cell stack incorporating two cells 1A and 1B superimposed on one another and connected in series. Such an arrangement enables even higher voltages per unit area to be produced than can be produced with single junction thin film solar cell arrays.

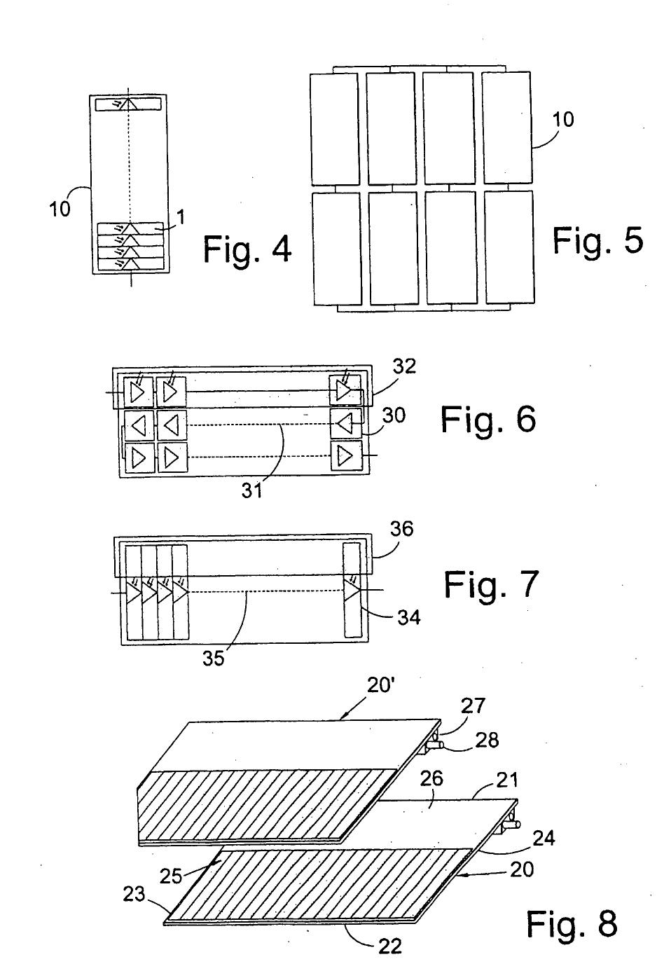

The solar cells in solar cell arrays are typically connected in series, either discretely or monolithically, within a solar cell module 10, as diagrammatically shown in FIG. 4, so as to provide an output voltage in excess of 1V. 28 to 40 solar cells may be connected in series to provide peak power voltages of the order of 16V. If the required system voltage exceeds that provided by each module, then a number of modules may be connected in series to achieve the required voltage. Parallel connections between modules (or strings of series connected modules) may then be needed to achieve the overall power output of the system, as shown diagrammatically in FIG. 5.

Solar cells are used in a wide range of different electrical energy producing applications, one major application being for the provision of electricity for use in buildings in which case the solar cell array may be mounted on the building structure. In many building applications the DC electricity produced by the solar cells is converted to AC for use within the building, typically to 110V or higher, for consistency with mains voltage. The conversion from DC to AC is readily achieved, for example by using an inverter. In order to optimise the performance of such an inverter, and to manage the current flow, it is convenient to design the system such that the DC voltage is a significant proportion of the AC output to be delivered, DC voltages in the range of 20V to 120V being particularly suitable. Lower voltages tend to reduce inverter efficiency and increase the current flow, leading to the need for large cables, whereas higher voltages represent more of a safety hazard. Generally voltages below 75V are recognised as being safer and require less stringent certification for certain products.

Known solar cell devices designed for building integration use discrete solar cells mechanically interconnected with one another to achieve voltages in the optimum range. Typically in excess of 50 series connected solar cells are required, and this renders such devices costly to produce. Also the voltage per unit area in all such devices is below 150V per m². Furthermore, as most standard roofing products (tiles, shingles, slates etc.) are relatively small, known solar roofing products are either dimensionally similar to such standard roofing products but generate low voltages (under 10V) so that they need to be series connected to achieve voltages in the preferred range, or generate voltages in the preferred range but are larger than standard roofing products. In many cases the solar roofing products are non-uniform in colour, either because of the area between the cells or because the cells are interconnected by reflective metal tabs, and thus do not look like traditional building materials. Also such products often use solar cells arranged in more than one row as shown in FIG. 6, and this may be disadvantageous when the products overlap one another and are therefore partially shaded.

It is an object of the invention to provide an element for forming part of the external envelope of a building which incorporates a solar cell array and overcomes a number of the disadvantages associated with known solar cell devices designed for building integration.

According to the present invention there is provided an element for forming part of the external envelope of a building, the element comprising a solar cell array incorporating a plurality of monolithically interconnected thin film solar cells on an electrically insulating substrate, and electrical terminal means for electrically connecting the solar cell array of the element to power output means and/or an adjacent element of similar form to the first mentioned element.

Such an external building element which may be a roof slate, tile or panel, for example, can be formed so as to be almost identical in appearance to a normal roofing slate, tile or panel, and can generate DC voltages in the range of 20V to 120V avoiding the necessity for a large number of modules to be connected in parallel to achieve the overall power output required. Also the individual elements may be electrically connected together and/or to the required output terminals in a simple manner making installation of the elements particularly straightforward.

In order that the invention may be more fully understood, reference will now be made, by way of example, to the accompanying drawings in which:

FIG. 1 is a graph of current against voltage for a typical solar cell;

FIGS. 2 and 3 are diagrammatic cross-sections through monolithically interconnected single junction and multi-junction solar cells;

FIG. 4 is a diagram of solar cells series connected in a solar module;

FIG. 5 is a diagram of solar cell modules connected in series and in parallel;

FIGS. 6 and 7 are diagrams illustrating two alternative solar cell arrangements within an external building element and the effect of a shadow falling on each;

FIG. 8 is a perspective view of two overlapping external building elements in accordance with the invention;

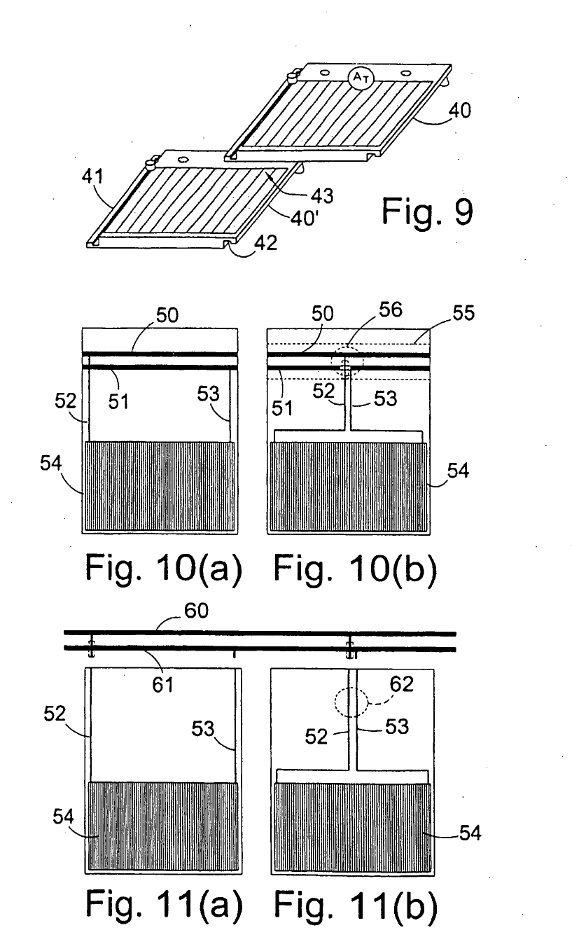

FIG. 9 is a perspective view of two interlocking external building elements in accordance with the invention;

FIGS. 10 and 11 illustrate two possible electrical connection arrangements for use with such external building elements; and

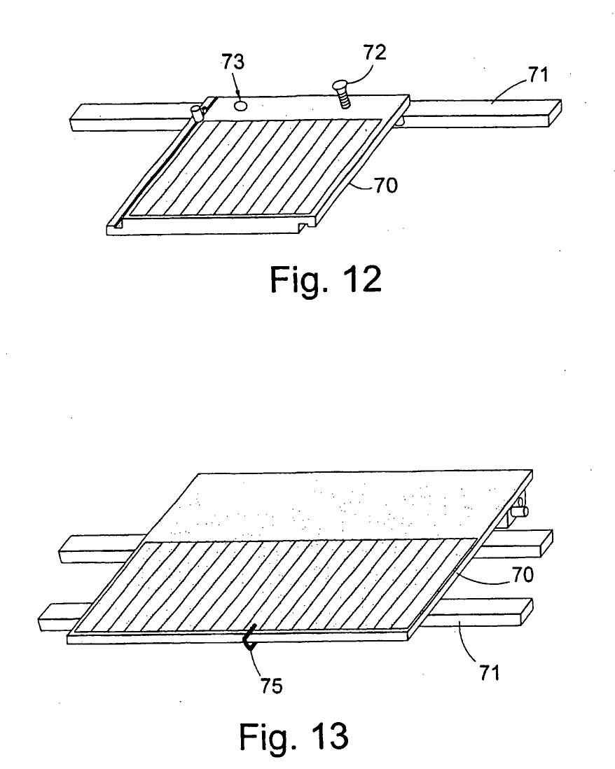

FIGS. 12 and 13 are perspective views showing two possible mounting arrangements for such external building elements.

A preferred embodiment of the invention is an external building element having the size and dimensions of a roofing slate but comprising a monolithically interconnected solar cell array within which a plurality of interconnected thin film solar cells are integrated on an electrically insulating substrate. The solar cells may either be single junction devices, as shown diagrammatically in FIG. 2, or may incorporate multi-junction devices of two or more superimposed solar cells (each designed, for example, to convert different parts of the incoming light spectrum), as shown diagrammatically in FIG. 3.

The cells may be positioned in one or more rows with the cells being electrically connected together in series and being connected by electrically conducting tracks to two output tracks. The output tracks of each element may be automatically interconnected to the output tracks of the adjacent elements when the elements are placed adjacent one another along a horizontal support rail so as to place the solar cell assemblies of the elements in parallel. Where the elements are positioned in overlapping rows, the s of the adjacent rows may be connected together by electrical interconnecting links so that all the elements of all the rows are connected in parallel.

Referring to FIG. 8 it is preferred that each element 20 is generally rectangular in form having parallel edges 21 and 22 intended to extend substantially horizontally when the element 20 is placed in position on a roof, and having further edges 23 and 24, also parallel to one another, intended to extend in the direction of inclination of the roof. The element 20 comprises an array of solar cells 25 integrally formed and monolithically interconnected on an insulating substrate, each cell 25 being aligned perpendicular to the horizontal edge 22 and generally parallel to the inclined edges 23 and 24. It will be seen that each of the cells 25 is elongate and extends over the same distance from close to the edge 22 over a proportion of the length of the edges 23 and 24 leaving an area 26 of the element 20 which does not need to contain solar cells. This area 26 may be left blank as it will, when installed, be covered by the adjacent row of roofing elements 20.

Although other arrangements of the solar cells on the underlying substrate are possible within the scope of the invention, the advantages of such an arrangement will be apparent by a comparison of FIGS. 6 and 7. In FIG. 6, the solar cell array comprises a series of substantially square solar cells 30 arranged in adjacent rows and connected in series in the manner shown by the lines 31, with the cells 30 being provided over substantially the whole of the area of the underlying substrate. In this case, as shown by the rectangle 32, the overlapping element or elements of the next row of elements overlaps at least some of the cells 30, and thus prevents those cells from outputting an electrical signal (or reduces the magnitude of the signal where the light reaches the cells only at a lower light intensity). Because the same current flows through all the cells in series and the current produced by each cell is proportional to the level of the incident light, the output current is restricted to the lowest output of the cells. If a cell is wholly in shadow so that it produces no current output, it follows that the whole series of cells will provide no current output. If a cell is partially obscured its output current will be reduced in proportion to the shadowed area, and the output current of the series of cells will be affected accordingly.

By contrast, if all the cells 34 are elongate and arranged parallel to one another, as shown in FIG. 7, whilst being connected in series as shown by the line 35, the effect of any shadowing by overlapping elements as shown by the rectangle 36 will be minimised. This is because such shadowing will tend to only partly reduce the current output of each cell, for example by a third, and, if all the cells are in shadow to the same extent, it follows that the output current of the whole array will be reduced only by the same amount. It is important to appreciate that any shadowing in elements in building-mounted systems is usually linear, since it is caused, for example, by overlapping rows of slates, overhanging eaves or other linear building features.

Referring again to FIG. 8 each of the elements 20 and 20′ shown therein incorporates a rib 27, which incorporates an interconnection projection 28 for engaging within a corresponding recess in the end of the rib of an adjacent element in order to lock the elements together. This connection also automatically provides an electrical connection between the output tracks of the elements. Such an element incorporating a thin film solar cell array may be substantially uniform in colour to provide a close visual match to natural and synthetic slates. The array is configured to provide a peak power voltage in excess of 20V and an open circuit voltage below 75V. The peak power voltage exceeds 150V per m² of active solar cell area.

FIG. 9 shows an alternative embodiment in which each of the elements 40 and 40′ incorporates a monolithically interconnected solar cell array 43, and oppositely facing profiles 41 and 42 along opposite edges, such that adjacent elements 40, 40′ can be mechanical interlocked by engagement of the profile 42 on the element 40′ with the profile 41 on the element 40. In this case the elements 40, 40′ are broadly flat in construction, and provide interlocking mechanical connection of adjacent elements and preferably also protection against water ingress. The alignment of the solar cell array and provision for overlapping rows may be as in the previously described embodiment.

These embodiments allows particularly relatively high voltages per unit area. No other products of the size of traditional tiles or slates achieve peak power voltages over 9V DC. For the reasons indicated above, peak power voltages in the range 20 to 120 V are most suitable. This embodiment allows peak power voltages over 20V and particularly in the range 20 to 120V. It is expected that elements with peak power voltages in the range 20 to 75 volts will be of primary interest initially. Additionally the open circuit voltage is likely to be below 75 volts, that is at a safer DC operating level.

FIGS. 10 and 11 show possible configurations for the electrical connections within each element. FIG. 10 shows electrical connection arrangements suitable for providing direct electrical connection between adjacent elements when such elements are mechanically interconnected. The electrical circuit shown at (a) comprises two horizontal bus-bar rails 50 and 51, which effect the parallel connections between neighbouring elements. The conductive tracks 52 and 53 provide the contacts between these bus-bar rails and the positive and negative terminations of the solar cell array 54.

The rails 50, 51 may be integral within the element as shown at (a) or in a separate assembly attached to or close to the element as indicated by the dotted rectangle 55 as shown at (b) in an alternative configuration. Similarly the connections to the solar cell array contacts may be within the element or made through a hole in the surface (or at the edges) of the element, as the indicated by the dotted hole 56 shown at (b). The electrical connections between neighbouring elements may be formed by any suitable electrical contact arrangement, such as male/female plug and socket connections for example.

FIG. 11 shows electrical connection arrangements suitable for connection to a separate wiring harness or bus-bar providing parallel connections between elements. In these arrangements the connections from the bus-bar rails 60 and 61 to each element by means of the conductive tracks 52 and 53 are required purely to provide the positive and negative contacts to the solar cell array. These connections may be made separately, as shown at (a), or together, as shown at (b), and either at the edge of the element, as shown at (a), or by way of a hole 62 through a surface, as shown at (b). The connections to the separate bus-bar or harness assembly may be formed by any suitable electrical contact arrangement, such as male/female plug and socket connections for example.

The elements may be mounted on the building structure by a wide variety of means. Ideally similar methods would be used as are used to apply to standard building products, such as the methods described below with reference to FIGS. 12 and 13. In FIG. 12 the element 70 is shown mounted on a roofing batten 71 using nails 72 or screws extending through holes 73 in the element. In FIG. 13 a hook 75 is attached to the roofing batten 71 and the element 70 is supported by the hook 75 and neighbouring elements. Each element may be mounted by one or more than one of the mounting means described.

The primary steps in the production of such solar building elements may be carried out as follows. The insulating substrate 2 is prepared, either by using a sheet of insulating material, or by applying an insulating coating to a sheet of a conductive material, and is configured to an appropriate size and prepared for processing. A conductive contact layer is applied to the substrate 2 and configured in a series of separate strips. This may be achieved either by a process in which the conductive layer is deposited in strips (such as by printing, or by deposition through a mask) or by a process in which the conductive layer is deposited as a continuous layer and is formed into strips by a subsequent processing step (such as by mechanical or laser scribing, or by etching) which removes thin sections of the layer. The solar cell semiconductor is then applied in contact with the contact layer, usually by sequential deposition of three sub-layers. In the case of multiple junction cells this sequence may be repeated. As in the case of the contact layer these sub-layers may be applied in separate strips, or the strips may be formed subsequently either to the deposition or to the application of the second contact layer, for example by any of the steps described above with reference to the fabrication of the first layer. The second contact layer is then applied in contact with the surface of the semiconductor layer. Again this second contact layer is divided into separate regions as described above leaving a series of narrow inter-cell isolation regions between adjacent cells. The relative alignment of these inter-cell isolation regions provides the monolithic series connection between the cells as previously described.

The element produced as described above is typically tested for electrical performance before further assembly. It may be cut into several smaller pieces to provide a solar cell array suitable for the particular element, conveniently for example to match the size of a standard building product. The further production steps may be carried out in several alternative sequences, but typically include the steps of attachment of at least two output conductors to the solar cell array, attachment of external connection means to these conductors, laying up of the solar cell array with other components to achieve the desired final shape and size of the product, and lamination or other assembly process to secure the element as an integral unit and provide appropriate environmental and electrical protection for the solar cell array, the conductors and other components.

Various modifications of the above described embodiments can be contemplated within the scope of the invention. For example the elements may employ multi-junction thin film solar cells arranged in the manner described and electrically connected in series. Furthermore the element may be configured to mimic a roofing tile or panel, or some other type of external building element, such as a building cladding panel or a building façade panel.

1. An element for forming part of the external envelope of a building, the element comprising a solar cell array incorporating a plurality of monolithically interconnected thin film solar cells on an electrically insulating substrate, and electrical terminal means for electrically connecting the solar cell array of the element to at least one of a power output means and adjacent element of similar form to the first-mentioned element.

2. An element according to claim 1, wherein the terminal means comprises an output track to which the solar cell array is connected and interconnection portions at the ends of the output track for electrically connecting the output track to at least one of the power output means and the output track of an adjacent element.

3. An element according to claim 2, wherein the interconnection portions comprise a projecting part at one end of the output track for engaging within a receiving part of the output track of an adjacent element, and a receiving part at the other end of the output track for receiving a projecting part of the output track of an adjacent element.

4. An element according to claim 2, wherein the terminal means is adapted to connect together the solar cell arrays of adjacent elements in parallel relative to the power output means.

5. An element according to claim 4, wherein at least some of the cells of the solar cell array are electrically connected in series to provide an output voltage in excess of one volt.

6. An element according to claim 2, wherein at least some of the cells of the solar cell array are electrically connected in parallel.

7. An element according to claim 2, which has an edge adapted to be horizontally disposed when installed in a building, and the cells of the solar cell array are elongated and extend substantially perpendicularly to the edge in a common plane.

8. An element according to claim 2, which has a region which is free of the cells of the solar cell array and which is adapted to be overlapped by another element when installed in a building.

9. An element according to claim 8, wherein the solar cell array incorporates a multiplicity of superimposed solar cell junctions.

10. An element according to claim 8, which is substantially rectangular and has a rib extending adjacent one edge by means of which the element may be suspended from a structural member.

11. An element according to claim 5, which is adapted to have a peak power output voltage in excess of 20V.

12. An element according to claim 11, which is adapted to have an open circuit output voltage less than 75V.

13. An element according claim 12, which is adapted to have a peak power output voltage in excess of 150V per square metre of active solar cell area.

14. An element according to claim 8, which is adapted to be used as a roofing slate, tile or panel and has the appearance of a conventional roofing slate, tile or panel not incorporating a solar cell array.

15. An element according to claim 7, which is adapted to be used as a building cladding or façade panel and has the appearance of a conventional building cladding or façade panel not incorporating a solar cell array.

16. An element according to claim 5, which has an edge adapted to be horizontally disposed when installed in a building, and the cells of the solar cell array are elongated and extend substantially perpendicularly to the edge in a common plane.

17. An element according to claim 16, which has a region which is free of the cells of the solar cell array and which is adapted to be overlapped by another element when installed in a building.

18. An element according to claim 17, which is adapted to be used as a roofing slate, tile or panel and has the appearance of a conventional roofing slate, tile or panel not incorporating a solar cell array.

19. An element according to claim 18, which is adapted to have a peak power output voltage in excess of 20V and less than 75V.

20. An element according claim 19, which is adapted to have a peak power output voltage in excess of 150V per square metre of active solar cell area.
